(19) United States
(12) Patent Application Publication
(10) Pub. No.: US 2005/0189597 A1
(43) Pub. Date: Sep. 1, 2005

(54) Semiconductor device featuring multi-layered electrode structure

(76) Inventors: Yuri Masuoka, Kanagawa (JP); Naohiko Kimizuka, Kanagawa (JP)

Correspondence Address: YOUNG & THOMPSON, 745 SOUTH 23RD STREET, 2ND FLOOR, ARLINGTON, VA, 22202, US

(21) Appl. No.: 11/068,432

(22) Filed: Mar. 1, 2005

(30) Foreign Application Priority Data
Mar. 1, 2004 (JP) 2004-056537

(51) Int. Cl. H01L 27/108

(52) U.S. Cl. 257/371

(57) ABSTRACT

In a semiconductor device including a semiconductor substrate (10; 56), at least one electrode structure (34, 36; 72, 74) is provided on a surface of the semiconductor substrate. The electrode structure is constructed as a multi-layered electrode structure including an insulating layer (34A, 36A; 72A, 74A) formed on the surface of the semiconductor substrate and composed of a dielectric material exhibiting a dielectric constant larger than that of silicon dioxide, a lower electrode layer (34B, 36B; 72B, 74B) formed on the insulating layer and composed of polycrystalline silicon, and an upper electrode layer (34C, 36C; 72D, 74D) formed on the lower electrode layer and composed of polycrystalline silicon. The lower electrode layer features an average grain size of polycrystalline silicon which is larger than that of polycrystalline silicon of the upper electrode layer.

### BACKGROUND OF THE INVENTION

1. Field of the Invention

The present invention relates to a semiconductor device featuring an electrode structure which includes an insulating layer, and an electrode formed on the insulating layer, and more particularly relates to a semiconductor device including metal oxide semiconductor (MOS) transistors, a dynamic random access memory (DRAM) device, a nonvolatile semiconductor memory device, and so on, each of which features such an electrode structure.

2. Description of the Related Art

For example, a MOS transistor, included in a semiconductor device, features an electrode structure, which is referred to as a gate electrode structure. In this MOS transistor, a source region and a drain region are produced in, for example, a silicon substrate, which is usually derived from a monocrystalline silicon wafer, and the gate electrode structure is constructed on the silicon substrate so as to be associated with the source and drain regions. Namely, the gate electrode structure includes a gate insulating layer formed as a silicon dioxide layer on the silicon substrate so as to bridge a space between the source region and the drain region to thereby define a channel region therebetween, and a gate electrode formed as a polycrystalline silicon layer on the gate insulating layer.

With the recent advance of miniaturization of semiconductor devices, the size of the gate electrode has become smaller, and the thickness of the gate insulating layer has become thinner. Thus, it is necessary to validly suppress a short-channel effect which may be caused in the channel region.

Usually, a lightly doped drain (LDD) structure is incorporated in the MOS transistor device for the suppression of the short-channel effect. In particular, a LDD region is produced in the silicon substrate as a part of each of the source and drain regions such that the channel region is defined between the LDD regions of the source and drain regions. An impurity density of the LDD regions is smaller than that of both the source and drain regions, and thus it is possible lo to decrease a creation of a depletion region in an interface between each of the LDD regions and the channel region, resulting in the suppression of the short-channel effect. Note, an extension region may be substituted for the LDD region. Also, note, a halo region may be associated with either of the LDD region or the extension region, to thereby further facilitate the suppression of the short-channel effect.

Also, for improvement of characteristics of the MOS transistor, it is well known that suitable impurities are implanted and diffused in the gate electrode to thereby diminish resistance of the gate electrode. For example, when the MOS transistor is of a P-channel type, p-type impurities, such as boron ions (B⁺) or the like, are doped in the gate electrode. When the MOS transistor is of an N-channel type, N-type impurities, such as arsenic ions (As⁺), phosphorus ions (P⁺) or the like, are implanted and diffused in the gate electrode.

In this case, a part of the impurities included in the gate electrode may be diffused in the gate insulating layer, and thus the impurities may react with the silicon atoms included in the gate insulating layer or silicon dioxide layer, to thereby produce defects therein, resulting in deterioration of the characteristic of the gate insulating layer.

In order to suppress the diffusion of the impurities in the gate insulating layer, it is proposed that the gate electrode be constructed as a multi-layered gate electrode, as disclosed in, for example, JP-A-04H-326766.

In particular, the multi-layered gate electrode is constructed by a first electrode layer formed on the gate insulating layer and composed of polycrystalline silicon, and a second electrode layer formed on the first electrode layer and composed of polycrystalline silicon, with grain sizes of the polycrystalline silicon in the second electrode layer being larger than those of the polycrystalline silicon in the first electrode layer. Thus, during the implantation/diffusion process in which the impurities are implanted and diffused in the multi-layered gate electrode, it is possible to suppress the diffusion of the impurities in the gate insulating layer, due to the existence of the second electrode layer featuring the large grain sizes of the polycrystalline silicon.

On the other hand, there is a demand for further advances in the miniaturization and integration of semiconductor devices including MOS transistors. In this case, it is necessary to diminish the thickness of the gate insulating layer to less than several nm in accordance with the scaling rule, before the further advance of the miniaturization and integration can be achieved. However, such a fine silicon dioxide layer can be no longer used as the gate insulating layer in a MOS transistor, because a tunnel current, caused when a bias voltage applied to the gate electrode, has a magnitude which cannot be ignored with respect to a source/drain current.

Thus, in order to achieve further advances in the miniaturization and integration of semiconductor devices including the MOS transistors, it is necessary to use a high-k material, exhibiting a dielectric constant of more than 6, as a substitute for the silicon dioxide material exhibiting the dielectric constant of 3.9, for the gate insulating layer.

As representative of a high-k material having the dielectric constant of more than 6, there are aluminum oxide, aluminum nitride, aluminum oxy-nitride, and aluminum silicate. Also, there are oxides, nitrides, oxy-nitrides, aluminates, and silicates, which are obtained from rare earth elements, such as zirconium (Zr), hafnium (Hf), tantalum (Ta), yttrium (Y), and lanthanoid (La, Ce, Pr, Nd, Pm, Sm. Eu, Gd, Tb, Dy, Ho, Er, Tm, Yb, Lu).

Although further advances in the miniaturization and integration of semiconductor devices are possible by using a high-k gate insulating layer composed of one of the aforesaid high-k materials, there is still the problem that the diffusion of the impurities in the high-k gate insulating layer must be suppressed when the impurities are implanted and diffused in the gate electrode to thereby diminish resistance of the gate electrode.

In addition, another problem to be solved occurs when the high-k gate insulating layer is used. In particular, aluminum elements or rare earth elements included in the high-k gate insulating layer may easily react with the silicon elements included in the polycrystalline silicon gate electrode, to thereby produce trap sites in the high-k gate insulating layer, resulting in considerable deterioration of the reliability and performance of the MOS transistor, as discussed in detail hereinafter.

### SUMMARY OF THE INVENTION

Therefore, a main object of the present invention is to provide a semiconductor device featuring an electrode structure, which includes a high-k insulating layer composed of a high-k material, and an electrode formed on the high-k insulating layer and composed of polycrystalline silicon, and which is constituted so as to be substantially free from the problems as discussed above.

In accordance with an aspect of the present invention, there is provided a semiconductor device comprising a semiconductor substrate, and at least one electrode structure provided on a surface of the semiconductor substrate. The electrode structure is constructed as a multi-layered electrode structure including an insulating layer formed on the surface of the semiconductor substrate and composed of a dielectric material exhibiting a dielectric constant larger than that of silicon dioxide, a lower electrode layer formed on the insulating layer and composed of polycrystalline material, and an upper electrode layer formed on the lower electrode layer and composed of polycrystalline material. The lower electrode layer features an average grain size of polycrystalline material which is larger than that of polycrystalline material of the upper electrode layer.

Preferably, for the polycrystalline material, polycrystalline silicon is used. Also, preferably, the lower electrode layer may have a thickness of less than approximately 50 nm, and the upper electrode layer has a thickness of less than approximately 200 nm.

The insulating layer may be composed of aluminum oxide, aluminum nitride, aluminum oxy-nitride, and aluminum silicate. Also, the insulating layer may be composed of one selected from a group consisting of oxides, nitrides, oxy-nitrides, aluminates, and silicates, which are obtained from zirconium (Zr), hafnium (Hf), tantalum (Ta), yttrium (Y), and lanthanoid (La, Ce, Pr, Nd, Pm, Sm, Eu, Gd, Tb, Dy, Ho, Er, Tm, Yb, Lu).

When the polycrystalline silicon is used for the polycrystalline material, the lower electrode layer may be formed as an amorphous silicon layer by using a chemical vapor deposition method at a process temperature falling a range from 400° C. to 600° C., and crystallization is caused in the amorphous silicone layer under a process temperature of more than 600° C., resulting in formation of the lower electrode layer.

Also, when the polycrystalline silicon is used for the polycrystalline material, the multi-layered electrode structure further may include an intermediate electrode layer intervened between the lower electrode layer and the upper electrode layer, and the intermediate electrode layer is formed as a silicon/germanium layer.

The semiconductor device may feature at least one metal oxide semiconductor transistor. In this case, the aforesaid multi-layered structure is defined as a multi-layered gate electrode structure for the metal oxide semiconductor transistor, the insulating layer serving as a gate insulating layer, the lower electrode layer serving as a lower gate electrode layer, the upper electrode layer serving as an upper gate electrode layer.

### BRIEF DESCRIPTION OF THE DRAWINGS

The above object and other objects will be more clearly understood from the description set forth below, with reference to the accompanying drawings, wherein:

FIG. 1A is a partial cross-sectional view of a silicon substrate, showing a first representative step of a production process for manufacturing a first embodiment of a semiconductor device featuring a complementary MOS transistor according to the present invention;

FIG. 1B is a partial cross-sectional view, similar to FIG. 1A, showing a second representative step of the production process according to the present invention;

FIG. 1C is a partial cross-sectional view, similar to FIG. 1B, showing a third representative step of the production process according to the present invention;

FIG. 1D is a partial cross-sectional view, similar to FIG. 1C, showing a fourth representative step of the production process according to the present invention;

FIG. 1E is a partial cross-sectional view, similar to FIG. 1D, showing a fifth representative step of the production process according to the present invention;

FIG. 1F is a partial cross-sectional view, similar to FIG. 1E, showing a sixth representative step of the production process according to the present invention;

FIG. 1G is a partial cross-sectional view, similar to FIG. 1F, showing a seventh representative step of the production process according to the present invention;

FIG. 1H is a partial cross-sectional view, similar to FIG. 1G, showing an eighth representative step of the production process according to the present invention;

FIG. 1I is a partial cross-sectional view, similar to FIG. 1H, showing a ninth representative step of the production process according to the present invention;

FIG. 1J is a partial cross-sectional view, similar to FIG. 1I, showing a tenth representative step of the production process according to the present invention;

FIG. 1K is a partial cross-sectional view, similar to FIG. 1J, showing an eleventh representative step of the production process according to the present invention;

FIG. 1L is a partial cross-sectional view, similar to FIG. 1K, showing a twelfth representative step of the production process according to the present invention;

FIG. 1M is a partial cross-sectional view, similar to FIG. 1L, showing a thirteenth representative step of the production process according to the present invention;

FIG. 1N is a partial cross-sectional view, similar to FIG. 1M, showing a fourteenth representative step of the production process according to the present invention;

FIG. 1P is a partial cross-sectional view, similar to FIG. 1N, showing a fifteenth representative step of the production process according to the present invention;

FIG. 1Q is a partial cross-sectional view, similar to FIG. 1P, showing a sixteenth representative step of the production process according to the present invention;

FIG. 1R is a partial cross-sectional view, similar to FIG. 1Q, showing a seventeenth representative step of the production process according to the present invention;

FIG. 1S is a partial cross-sectional view, similar to FIG. 1R, showing an eighteenth representative step of the production process according to the present invention;

FIG. 2 is a graph for explaining an increase characteristic of a depletion region created in a multi-layered gate electrode structure according to the present invention;

FIG. 3 is a graph for explaining a gate leakage current in a MOS transistor featuring a gate electrode structure including a high-k gate insulating layer, and a polycrystalline electrode layer formed thereon;

FIG. 4 is a graph for explaining evaluation of a gate leakage current in a MOS transistor according to the present invention;

FIG. 5 is a graph for explaining evaluation of variation of a gate threshold voltage in a MOS transistor according to the present invention;

FIG. 6 is a graph for explaining evaluation of a hysteresis characteristic of a gate threshold voltage in FIG. 7 is a graph for explaining evaluation of a time dependent dielectric breakdown (TDDB) lifetime of a MOS transistor according to the present invention;.

FIG. 8 is a graph for explaining evaluation of a positive bias temperature instability (PBTI) lifetime of a MOS transistor according to the present invention;

FIG. 9A is a partial cross-sectional view of a silicon substrate, showing a first representative step of a production process for manufacturing a second embodiment of a semiconductor device featuring a complementary MOS transistor according to the present invention;

FIG. 9B is a partial cross-sectional view, similar to FIG. 9A, showing a second representative step of the production process according to the present invention;

FIG. 9C is a partial cross-sectional view, similar to FIG. 9B, showing a third representative step of the production process according to the present invention; and

FIG. 9D is a partial cross-sectional view, similar to FIG. 9C, showing a fourth representative step of the production process according to the present invention.

### DESCRIPTION OF THE PREFERRED EMBODIMENTS

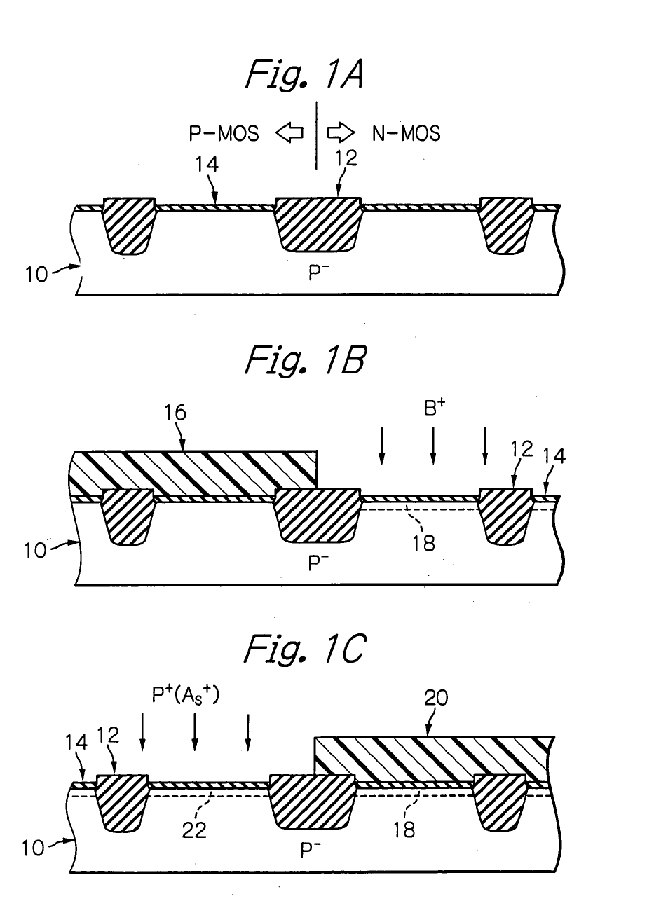

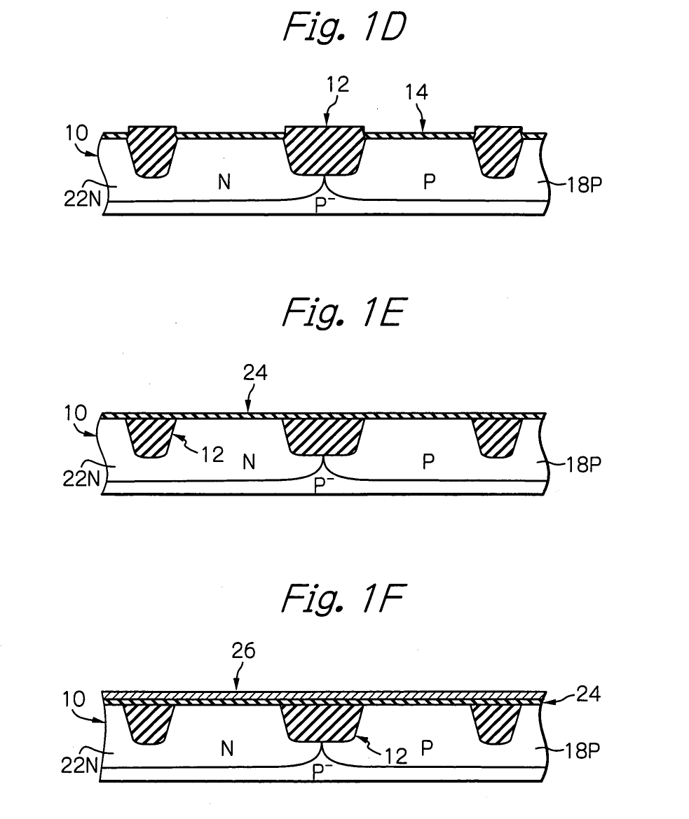

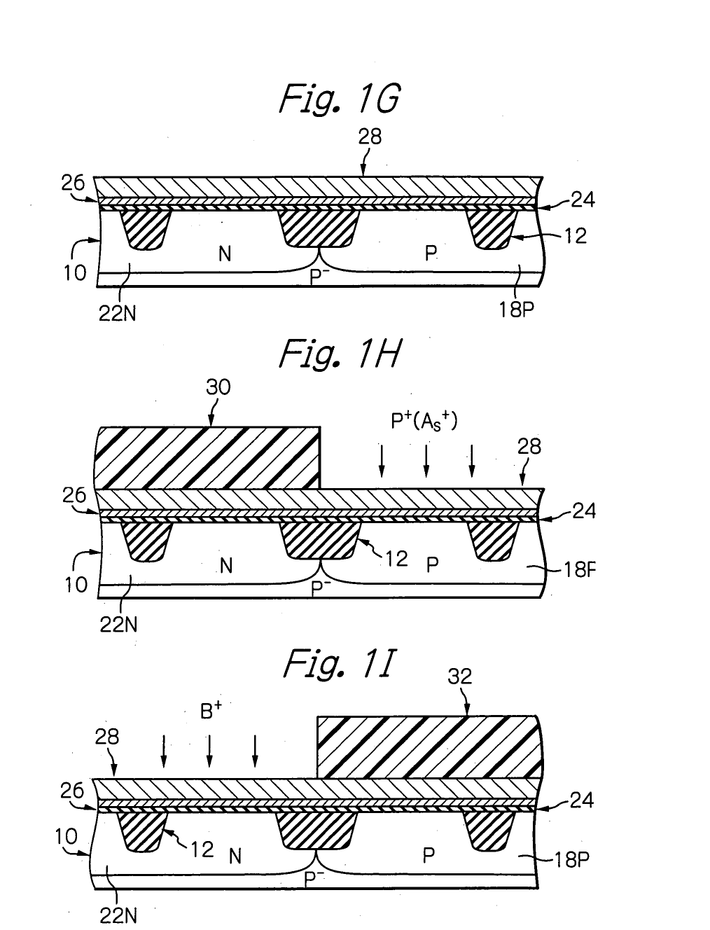

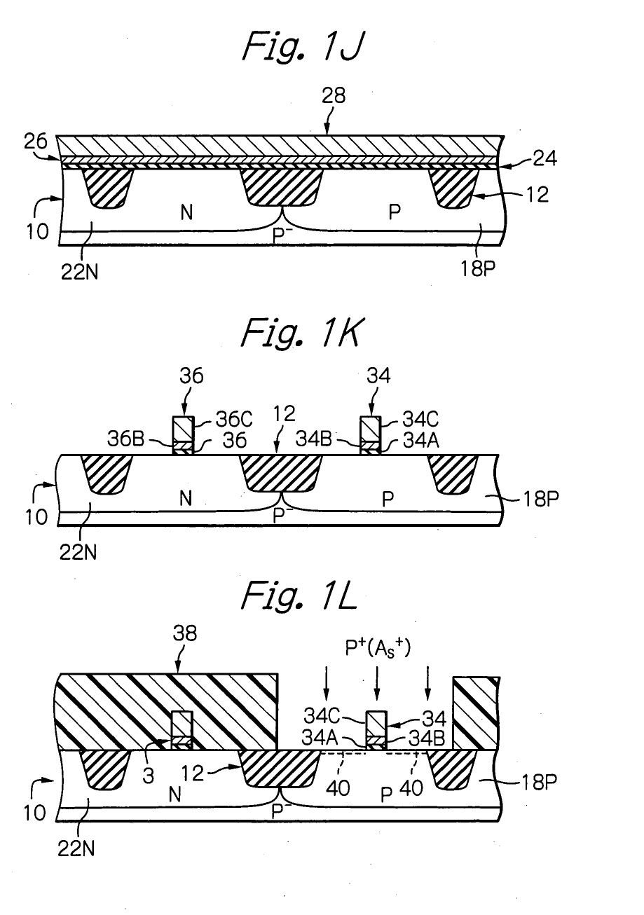

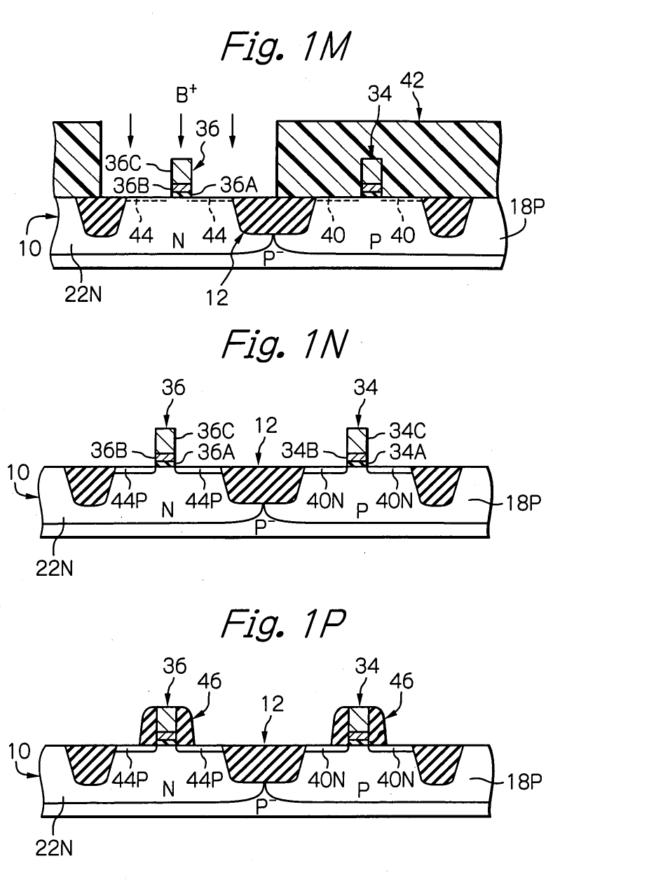

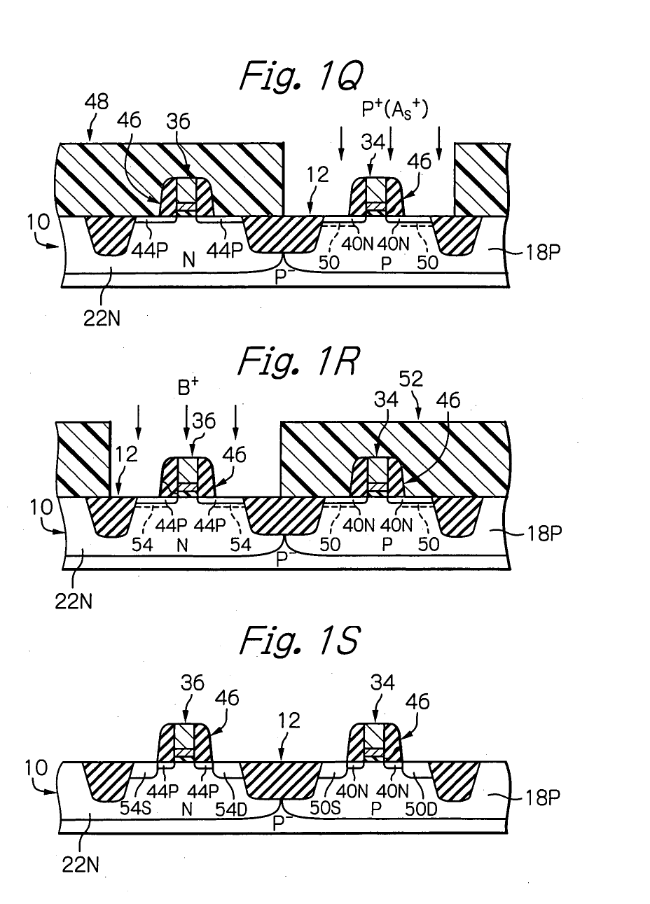

With reference to FIGS. 1A to 1N and FIGS. 1P to 1S, a production process for manufacturing a first embodiment of a semiconductor device featuring a complementary MOS transistor according to the present invention will be now explained.

First, as shown in FIG. 1A, a p⁻-type semiconductor substrate 10, which is derived from, for example, a p⁻-type monocrystalline silicon wafer, is prepared. A surface of the semiconductor substrate 10 is sectioned into a plurality of chip areas by forming scribe lines therein, and a part of one chip area is illustrated in a cross sectional in FIG. 1A. In this drawing, reference 12 generally indicates an element-isolation layer, which is formed in the chip area concerned, by using a STI (shallow-trench isolation) method, such that a P-channel type MOS transistor-formation area “P-MOS” and an N-channel type MOS transistor-formation area “N-MOS” are defined on the surface of the chip area. Also, the semiconductor substrate 10 is already subjected to a thermal oxidization process, so that a sacrifice silicon dioxide layer 14 is formed on the surface of the chip area.

Note, the formation of the element-isolation layer 12 may be carried out by using a LOCOS (local oxidation of silicon) method, if necessary.

After the formation of the sacrifice silicon dioxide layer 14 is completed, as shown in FIG. 1B, a photoresist layer 16 is formed on the surface of the semiconductor substrate 10, and is patterned by using a photolithography process and an etching process such that the N-channel type MOS transistor-formation area “N-MOS” is exposed to the outside. Then, p-type impurities, such as boron ions (B⁺) or the like, are implanted in the exposed N-channel type MOS transistor-formation area “N-MOS” to thereby produce a P-type impurity-implanted region 18 therein. Note, boron fluoride (BF₂) may be used for the implantation of the boron ions (B⁺). Subsequently, the patterned photoresist layer 16 is removed from the surface of the semiconductor substrate 10 by using an ashing process, a wet peeling process or the like.

After the removal of the patterned photoresist layer 16 is completed, as shown in FIG. 1C, a photoresist layer 20 is formed on the surface of the semiconductor substrate 10, and is patterned by using a photolithography process and an etching process such that the P-channel type MOS transistor-formation area “P-MOS” is exposed to the outside. Then, N-type impurities, such as phosphorus ions (P⁺), arsenic ions (As⁺) or the like, are implanted in the exposed P-channel type MOS transistor-formation area “P-MOS”, to thereby produce an N-type impurity-implanted region 22 therein. Subsequently, the patterned photoresist layer 20 is removed from the surface of the semiconductor substrate 10 by using an ashing process, a wet peeling process or the like.

After the removal of the patterned photoresist layer 20 is completed, the semiconductor substrate 10 is subjected to an annealing process in which the implanted P-type impurities and N-type impurities are activated and diffused so that the P-type impurity-implanted region 18 and the P-type impurity-implanted region 22 are produced as a P-type well region 18P and an N-type well region 22N in the N-channel type MOS transistor-formation area “N-MOS” and the P-channel type MOS transistor-formation area “P-MOS”, respectively, as shown in FIG. 1D.

After the production of the P-type and N-type well regions 18P and 22N is completed, the semiconductor substrate 10 is subjected to a wet etching process, in which the sacrifice silicon dioxide layer 14 are etched and removed from the surface semiconductor substrate 10. Note, in this wet etching process, a part of the element-isolation layer 12 is etched and removed to thereby flatten the surface of the semiconductor substrate 10.

Then, as shown in FIG. 1E, a high-k insulating layer 24 is formed on the flattened surface of the semiconductor substrate 10 by using an atomic-layer deposition (ALD) method. For example, the high-k insulating layer 24 may be formed as a hafnium oxide (HfO) layer. In this case, in the ALS method, an organic hafnium source gas, such as tertiary butoxy-hafnium (Hf(OtBu)₄), acetylacetonate hafnium (Hf(Acac)₄), diethylamino-hafnium (Hf(NEt₂)₄) or the like, is used together with oxygen radicals.

In particular, the semiconductor substrate 10 is heated to a temperature of approximately 400° C., and hydrogen is eliminated from the surface of the semiconductor substrate 10. Then, the semiconductor substrate 10 is alternately exposed to the organic hafnium source gas and the oxygen radials, resulting in the formation of the high-k insulating layer or hafnium oxide layer 24 on the surface of the semiconductor substrate 10.

When it is desired that the high-k insulating layer 24 is formed as a hafnium silicon oxy-nitride (HfSiON) layer, a nitrogen gas is substituted for the oxygen radicals in the aforesaid ALD method. Otherwise, nitrogen radicals, which are derived from ammonia, may be used as a substitute for the nitrogen gas. Also, when it is desired that the high-k insulating layer 24 is formed as a hafnium oxy-nitride (HfON) layer, a nitric-oxide-based gas, containing NO, N₂O or NO₂, is substituted for the oxygen radicals in the aforesaid ALD method.

The high-k insulating layer 24 may be formed as one of a zirconium oxide (ZrO) layer, and a zirconium oxy-nitoride (ZrON) layer. In this case, an organic zirconium source gas, such as tertiary butoxy-zirconium (Zr(OtBu)₄), acetylacetonate zirconium (Zr(Acac)₄), diethylamino-zirconium (Zr(NEt₂)₄) or the like, is substituted for the organic hafnium source gas in the aforesaid ALD method.

When a tri-methyl aluminum (TMA: Al(CH₃)₃) gas is added to the aforesaid organic hafnium source gas, the high-k insulating layer 24 is formed as a hafnium aluminate layer. Also, when the tri-methyl aluminum gas (TMA: Al(CH₃)₃) is added to the aforesaid organic zirconium source gas, the high-k insulating layer 24 is formed as a zirconium aluminate layer.

When a tetra-methyl silane gas is added to the organic hafnium source gas, the high-k insulating layer 24 is formed as a hafnium silicate layer. Also, when the tetra-methyl silane gas is added to the organic zirconium source gas, the high-k insulating layer 24 is formed as a zirconium silicate layer.

In the above-mentioned ALD method, when only the tri-methyl aluminum (TMA: Al(CH₃)₃) gas is used as the source gas, is the high-k insulating layer formed as an aluminum oxide (Al₂O₃) layer.

Note, of course, it should be understood that the formation of the high-k insulating layer 24 may be carried out by using an organic metal source gas containing another rare earth element, tantalum (Ta), yttrium (Y), lanthanoid (La, Ce, Pr, Nd, Pm, Sm, Eu, Gd, Tb, Dy, Ho, Er, Tm, Yb, Lu) or the like.

The formation of the high-k insulating layer 24 may be carried out by using another method including either a reactive sputtering process or a metal sputtering process, and a thermal oxidization process. Namely, for example, after an aluminum layer is formed on the surface of the semiconductor substrate 10 by using the sputtering process, it is reformed as an aluminum oxide layer by using the thermal oxidization process. Of course, a rare earth metal layer may be formed as a substitute for the aluminum layer. Further, it is possible to carry out the formation of the high-k insulating layer 24 by using a suitable chemical vapor deposition (CVD) method.

After the formation of the high-k insulating layer 24 is completed, as shown in FIG. 1F, an amorphous silicon layer 26 is formed on the high-k insulating layer by using a suitable CVD method, at a low process temperature falling within a range from approximately 400° C. to approximately 600° C., whereby it is possible to effectively suppress reaction between the aluminum elements or rare earth elements included in the high-k insulating layer 24 and the silicon elements included in the amorphous silicon layer 26, resulting in suppression of production of trap sites in the high-k insulating layer 24.

When the amorphous silicon layer 26 is grown to a thickness of less than approximately 50 nm, the process temperature is raised to more than 600° C., so that a polycrystalline silicon layer 28 is formed on the amorphous silicon layer 26, as shown in FIG. 1G. Note, a thickness of the polycrystalline silicon layer 28 is less than approximately 200 nm. During the formation of the polycrystalline silicon layer 28, the process temperature of more than 600° C. causes crystallization in the amorphous silicone layer 26, so that the amorphous silicone layer 26 is reformed as a polycrystalline silicon layer.

Note, the polycrystalline silicon layer 26 features an average grain size which is larger than that of the polycrystalline silicon layer 28 which is formed at the high process temperature of more than 600° C. In short, both the lower polycrystalline silicon layer 26 featuring the large grain size and the upper polycrystalline silicon layer 28 featuring the small grain size are formed on the high-k insulating layer 24.

After both the lower and upper polycrystalline silicon layers 26 and 28 are completed, as shown in FIG. 1H, a photoresist layer 30 is formed on the upper polycrystalline silicon layer 28, and is patterned by using a photolithography process and an etching process such that the N-channel type MOS transistor-formation area “N-MOS” is exposed to the outside. Then, N-type impurities, such as phosphorus ions (P⁺), arsenic ions (As⁺) or the like, are implanted in both the lower and upper polycrystalline silicon layers 26 and 28 at the exposed N-channel type MOS transistor-formation area “N-MOS”. Thereafter, the patterned photoresist layer 30 is removed from the upper polycrystalline silicon layer 28 by using an ashing process, a wet peeling process or the like.

After the removal of the patterned photoresist layer 30 is completed, a photoresist layer 32 is formed on the upper polycrystalline silicon layer 28, and is patterned by using a photolithography process and an etching process such that the P-channel type MOS transistor-formation area “P-MOS” is exposed to the outside, as shown in FIG. 1I. Then, P-type impurities, such as boron (B⁺) or the like, are implanted in both the lower and upper polycrystalline silicon layers 26 and 28 at the exposed P-channel type MOS transistor-formation area “P-MOS”. Note, boron fluoride (BF₂) may be used for the implantation of the boron ions (B⁺). Thereafter, the patterned photoresist layer 32 is removed from the upper polycrystalline silicon layer 28 by using an ashing process, a wet peeling process or the like, as shown in FIG. 1J.

After the removal of the patterned photoresist layer 32 is completed, the semiconductor substrate 10 is subjected to an annealing process, in which the N-type and P-type impurities are activated and diffused in the lower and upper polycrystalline silicon layers 26 and 28, to thereby diminish resistance of both the polycrystalline silicon layers 26 and 28. Note, during the annealing process, it is possible to suppress diffusion of the impurities in the high-k insulating layer 24 due to the large grain size of the lower polycrystalline silicon layer 26, resulting in suppression of production of defects in the high-k insulating layer 24.

After the annealing process is completed, the high-k insulating layer 24 and both the polycrystalline silicon layers 26 and 28 are patterned by a photolithography process and an etching process, such that gate electrode structures 34 and 36 are defined on the surfaces of the respective P-type and N-type well regions 18P and 22N, as shown in FIG. 1K.

The gate electrode structure 34 is obtained as a multi-layered structure including a high-k gate insulating layer 34A derived from the high-k insulating layer 24, a first gate electrode layer 34B derived from the polycrystalline silicon layer 26, and a second gate electrode layer 34C derived from the polycrystalline silicon layer 28, and the first and second gate electrode layers 34B and 34C feature the P-type impurities diffused therein.

Similarly, the gate electrode structure 36 is obtained as a multi-layered structure including a high-k gate lo insulating layer 36A derived from the high-k insulating layer 24, a first gate electrode layer 36B derived from the polycrystalline silicon layer 26, and a second gate electrode layer 36C derived from the polycrystalline silicon layer 28, and the first and second gate electrode layers 36B and 36C feature the P-type impurities diffused therein.

After the definition of the gate electrode structures 34 and 36 is completed, as shown in FIG. 1L, a photoresist layer 38 is formed on the surface of the semiconductor substrate 10, and is patterned by using a photolithography process and an etching process such that the N-channel type MOS transistor-formation area “N-MOS” is exposed to the outside. Then, N-type impurities, such as phosphorus ions (P⁺), arsenic ions (As⁺) or the like, are implanted in the P-type well region 18P by using the gate electrode structure 34 as a mask, to thereby produce N-type impurity-implanted regions 40 therein. Thereafter, the patterned photoresist layer 38 is removed from the surface of the semiconductor substrate 10 by using an ashing process, a wet peeling process or the like.

After the removal of the patterned photoresist layer 38 is completed, as shown in FIG. 1M, a photoresist layer 42 is formed on the surface of the semiconductor substrate 10, and is patterned by using a photolithography process and an etching process such that the P-channel type MOS transistor-formation area “P-MOS” is exposed to the outside. Then, P-type impurities, such as boron ions (P⁺) or the like, are implanted in the N-type well region 22N by using the gate electrode structure 36 as a mask, to thereby produce P-type impurity-implanted regions 44 therein. Note, boron fluoride (BF₂) may be used for the implantation of the boron ions (B⁺). Thereafter, the patterned photoresist layer 42 is removed from the surface of the semiconductor substrate 10 by using an ashing process, a wet peeling process or the like.

After the removal of the patterned photoresist layer 42 is completed, the semiconductor substrate 10 is subjected to an annealing process in which the implanted N-type impurities and P-type impurities are activated and diffused in the respective P-type and N-type well regions 18P and 22N, so that the N-type impurity-implanted regions 40 and the P-type impurity-implanted regions 44 are produced as respective lightly-dosed drain (LDD) regions 40N and 44P in the P-type and N-type well regions 18P and 22N, as shown in FIG. 1N.

This annealing process may be carried out under a nitrogen atmosphere or a nitrogen/oxygen atmosphere at a process temperature from 800° C. to 1,000° C. over an annealing time from 0 sec. to 10 sec. Usually, the annealing time is defined as a time which is counted from a time point when an atmosphere temperature has reached a predetermined temperature falling within the range from 800° C. to 1,000° C., and thus there may be the definition of the annealing time=0. The annealing process, in which the annealing time is set as 0 sec., is called a spike annealing process. Namely, in the spike annealing process, as soon as the process temperature has reached the predetermined temperature, it is lowered.

Note, during the annealing process (FIG. 1N), it is possible to suppress the diffusion of the impurities in the high-k gate insulating layers 34A and 36A due to the existence of the first gate electrode layers 34B and 36B featuring the large grain size.

After the annealing process (FIG. 1N) is completed, an insulating layer (not shown), which is composed of a suitable insulating material, such as silicon dioxide, silicon nitride or the like, is formed on the surface of the semiconductor substrate 10 by using a suitable CVD process, and is etched back in a well-known manner, so that a side wall 46 is formed on a peripheral side face of each of the gate electrode structures 34 and 36, as shown in FIG. 1P.

After the formation of the side walls 46 is completed, as shown in FIG. 1Q, a photoresist layer 48 is formed on the surface of the semiconductor substrate 10, and is patterned by using a photolithography process and an etching process such that the N-channel type MOS transistor-formation area “N-MOS” is exposed to the outside. Then, N-type impurities, such as phosphorus ions (P⁺), arsenic ions (As⁺) or the like, are implanted in the P-type well region 18P by using the side wall 46 of the gate electrode structure 34 as a mask, to thereby produce N-type impurity-implanted regions 50 therein.

Thereafter, the patterned photoresist layer 48 is removed from the surface of the semiconductor substrate 10 by using an ashing process, a wet peeling process or the like.

After the removal of the patterned photoresist layer 48 is completed, as shown in FIG. 1R, a photoresist layer 52 is formed on the surface of the semiconductor substrate 10, and is patterned by using a photolithography process and an etching process such that the P-channel type MOS transistor-formation area “P-MOS” is exposed to the outside. Then, P-type impurities, such as boron ions (P⁺) or the like, are implanted in the N-type well region 22N by using the side wall 40 of the gate electrode structure 36 as a mask, to thereby produce P-type impurity-implanted regions 54 therein. Note, boron fluoride (BF₂) may be used for the implantation of the boron ions (B⁺). Thereafter, the patterned photoresist layer 52 is removed from the surface of the semiconductor substrate 10 by using an ashing process, a wet peeling process or the like.

After the removal of the patterned photoresist layer 52 is completed, the semiconductor substrate 10 is subjected to an annealing process in which the implanted N-type impurities and P-type impurities are activated and diffused in the respective P-type and N-type well regions 18P and 22N, so that the respective N-type impurity-implanted regions 50 are produced as a source region 50S and a drain region 40D in the p-type well region 18P, and so that the respective P-type impurity-implanted regions 54 are produced as a source region 54S and a drain region 54D in the N-type well region 22N.

Note, during the annealing process (FIG. 1S), it is possible to suppress the diffusion of the impurities in the high-k gate insulating layers 34A and 36A due to the existence of the first gate electrode layers 34B and 36B featuring the large grain size.

Thereafter, an insulating interlayer (not shown) is formed on the surface of the semiconductor substrate 10 by using a suitable CVD process, and contact plugs (not shown) are formed in the insulating interlayer so as to be electrically connected to the source regions (50S, 54S) and the drain regions (50D, 54D). Then, the semiconductor substrate 10 is subjected to various processes for forming a multi-layered wiring arrangement thereon, and is then subjected to a dicing process, in which it is cut along the scribe lines, whereby the semiconductor devices are separated from each other, resulting in the manufacture of the first embodiment of the semiconductor device according to the present invention.

In general, a depletion region is liable to be created in an interface between a gate electrode layer and a gate insulating layer, resulting in deterioration of performance of a MOS transistor. The width of the depletion region depends upon a resistance of the gate electrode layer. Namely, the larger the resistance of the gate electrode layer, the wider the depletion region created in the interface between the gate electrode layer and the gate insulating layer.

In the above-mentioned embodiment, the first gate electrode layer (34B, 36B) has a resistance larger than that of the second gate electrode layer (34C, 36C), because the grain size of the first electrode layer (34B, 36B) is larger than that of the second gate electrode layer (34C, 36C). Thus, a thickness of the first gate electrode layer (34C, 36B) is very significant to suppress a creation of a depletion in an interface between the high-k insulating layer (34A, 36A) and the first gate electrode layer (34B, 36B).

In order to investigate a relationship between the thickness of the first gate electrode layer (34C, 36C) and the width of the depletion region, a test was performed by the inventors.

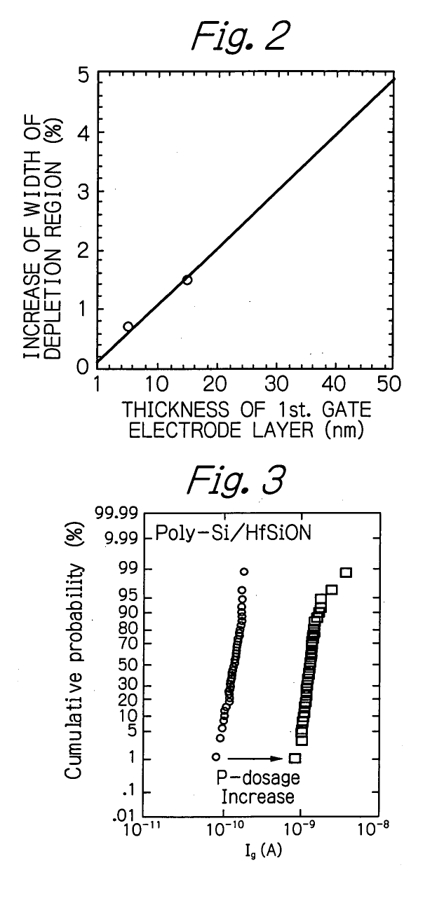

The test results are shown in a graph of FIG. 2. In this graph, the abscissa represents a variation of the thickness of the first gate electrode layer (34B, 36B), and the ordinate represents an increase of a width of a depletion region which was created in an interface between the high-k insulating layer (34A, 36A) and the second gate electrode layer (34C, 36C) directly formed thereon. Namely, when the first gate electrode layer (34B, 36B) was not intervened between the high-k insulating layer (34A, 36A) and the second gate electrode layer (34C, 36C), the increase of the width of the depletion region was naturally 0%.

As is apparent from the graph of FIG. 2, the thicker the thickness of the first gate electrode layer (34B, 36B), the larger the increase of the width of the depletion region. For example, when the first electrode layer (34B, 36B) had a thickness of 50 nm, the increase of the depletion region was approximately 5%.

The 5% increase of the width of the depletion region is allowable when the performance of the MOS transistor is taken into consideration. Thus, in the above-mentioned embodiment, the thickness of the first gate electrode layer (34B, 36B) should not exceed approximately 50 nm.

On the other hand, it is preferable that the second gate electrode layers 34C and 36C become thicker so that a resistance of both the first and second gate electrode layers (34B and 34C; and 36B and 36C) can be made smaller. Namely, the thinner the thickness of the second gate electrode layer, the larger the influence of the resistance of the first gate electrode layer (34B, 36C) on the resistance of both the first and second gate electrode layers (34B and 34C; and 36B and 36C).

Nevertheless, the thickness of the second gate electrode layer (34C, 36C) should not exceed approximately 200 nm so that the formation of the gate electrode structures 34 and 36 can be easily carried out. Namely, when the thickness of the polycrystalline silicon layer 38 exceeds approximately 200 nm, it is difficult to form the gate electrode structures 34 and 36 by subjecting the polycrystalline silicon layer 38 to the etching process (FIG. 1K).

Also, various tests were performed by the inventors to evaluate the semiconductor device according to the present invention, as stated below.

Evaluation for Gate Leakage Current

When defects are produced in the high-k gate insulating layer (34A, 36B) due to diffusion of the impurities therein, they cause a gate leakage current. Thus, the gate leakage current should be suppressed before the performance of the MOS transistor according to the present invention can be evaluated to be superior.

First, a plurality of referential samples were produced, and each of the referential samples featured a gate electrode structure including a high-k (HfSiON) gate insulating layer, and a polycrystalline electrode layer formed thereon. The referential samples were divided into two groups: a first group subjected to a small amount of phosphorus (P) dosage; and a second group subjected to a large amount of phosphorus (P) dosage.

Note, the high-k (HfSiON) gate insulating layer had a thickness which is equivalent to a silicon dioxide layer having a thickness of 1.6 nm.

A gate leakage current was measured with respect to each of the referential samples included in the first and second groups. The test results are shown in a graph of FIG. 3. In this graph, the abscissa represents a gate leakage current, and the ordinate represents a cumulative possibility. Also, symbol “◯” represents the measured gate leakage currents of the referential samples included in the first group, and symbol “□” represents the measured gate leakage currents of the referential samples included in the second group.

As is apparent from the graph of FIG. 3, as the amount of P-type impurity dosage was increased, an amount of gate leakage current was increased as indicated by an arrow in the graph of FIG. 3. In short, the test results proved that the defects which were produced in the high-k (HfSiON) gate insulating layer due to the phosphorus dosage, caused the gate leakage current.

Subsequently, a group A of capacitor samples and a group B of capacitor samples were produced. Note, each of the capacitor samples included in the groups A and B had an area size of approximately 1 mm.

Each of the capacitor samples included in the group A featured an electrode structure including a dielectric (HfSiON) layer corresponding to the high-k gate insulating layer (34A, 36A), and an electrode layer which formed thereon and corresponding to the second gate electrode layer (34C, 36C).

Each of the capacitor samples included in the group B featured an electrode structure which was equivalent to the gate electrode structure (34, 36). Namely, this electrode structure included a dielectric (HfSiON) layer corresponding to the high-k gate insulating layer (34A, 36A), a first electrode layer formed on the dielectric layer and corresponding to the first gate electrode layer (34B, 36B), and a second electrode layer formed on the first electrode layer and corresponding to the second gate electrode layer (34C, 36C).

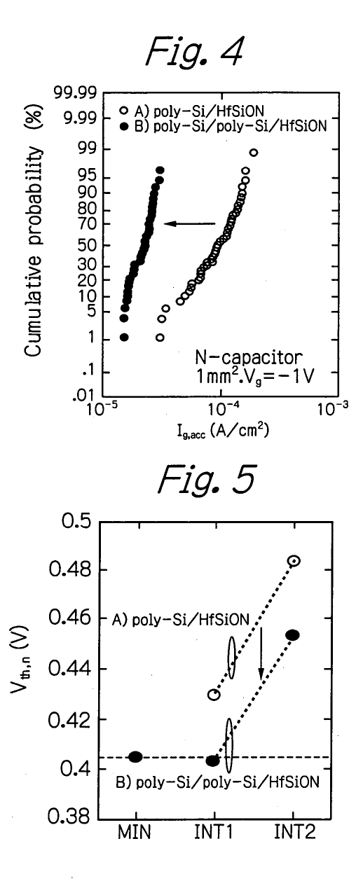

The groups A and B were subjected to an amount of phosphorous dosage. Then, a leakage current was measured with respect to each of the capacitor samples included in the groups A and B by applying a voltage of −1 volt to the capacitor samples. The test results are shown in a graph of FIG. 4. In this graph, the abscissa represents a leakage current, and the ordinate represents a distribution cumulative possibility. Also, symbol “◯” represents the measured leakage currents of the capacitor samples included in the group A, and symbol “●” represents the measured leakage currents of the capacitor samples included in the group B.

As is apparent from the graph of FIG. 4, the leakage currents of the capacitor samples included in the group B became smaller in comparison with the leakage current of the capacitor samples included in the group A. Thus, the tests proved that the gate leakage current could be considerably suppressed in the MOS transistor according to the present invention.

### Evaluation for Variation of Gate Threshold Voltage

When trap sites are produced in the high-k gate insulating layer (34A, 36A), a gate threshold voltage is variable due to the electrons trapped by the trap sites. Thus, it is necessary to suppress the variation of the gate threshold voltage before the performance of the MOS transistor according to the present invention can be evaluated to be superior.

First, a group A of N-channel type MOS transistor samples, which was divided into a plurality of subgroups, were produced. Each of these N-channel type MOS transistor samples featured a gate electrode structure including a high-k (HfSiON) gate electrode layer, and a gate electrode layer corresponding to the second gate electrode layer 34C.

In the group A, each of the gate electrode structures of the MOS transistors included in each subgroup of the group A was subjected to substantially the same amount of phosphorous dosage as each other, but the subgroups of the group A could be distinguished from each other in that the amount of phosphorous dosage, to which the gate electrode structures of the MOS transistors included in one subgroup were subjected, was different from the amount of phosphorous dosage to which the gate electrode structures of the MOS transistors included in another subgroup were subjected.

Also, a group B of N-channel type MOS transistor samples, which was divided into a plurality of subgroups, were produced by using the production method according to the present invention. Namely, each of these N-channel type MOS transistor samples featured a gate electrode structure which was equivalent to the gate electrode structure 34. Namely, the gate electrode included a high-k (HfSiON) gate layer corresponding to the high-k gate insulating layer 34A, a first electrode layer formed on the first gate electrode layer and corresponding to the first gate electrode layer 34B, and a second electrode layer formed on the first electrode layer and corresponding to the second gate electrode layer 34C.

Note, in the groups A and B, the high-k (HfSiON) gate insulating layer had a thickness which is equivalent to a silicon dioxide layer having a thickness of 1.6 nm.

Similar to the aforesaid group A, in the group B, each of the gate electrode structures of the MOS transistors included in each subgroup of the group B was subjected to substantially the same amount of phosphorous dosage as each other, but the subgroups of the group B could be distinguished from each other in that the amount of phosphorous dosage, to which the gate electrode structures of the MOS transistors included in one subgroup were subjected, was different from the amount of phosphorous dosage to which the gate electrode structures of the MOS transistors included in another subgroup were subjected.

A gate threshold voltage was measured with respect to each of the MOS transistor samples included in the groups A and B. The test results are shown in a graph of FIG. 5. In this graph, the abscissa represents an amount of phosphorous dosage, and the ordinate represents a variation of a gate threshold voltage. Note, in the abscissa, “MIN” represents the minimum amount of phosphorous dosage; “INT1” represents an intermediate amount of phosphorous dosage; and “INT2” represents an intermediate amount of phosphorous dosage. Also, symbol “◯” represents the measured gate threshold voltages of the MOS transistor samples included in the group A, and symbol “●” represents the measured gate threshold voltages of the MOS transistor samples included in the group B.

As is apparent from the graph of FIG. 5, the gate threshold voltage was substantially invariable in the MOS transistors included in the subgroups of the group B, which were featured by an amount of phosphorous dosage falling in a range between the minimum amount “MIN” of phosphorous dosage and the intermediate amount of phosphorous dosage “INT1”. On the contrary, the gate threshold voltage was varied considerably in MOS transistors included in the subgroup of the group A, which were featured by the intermediate amount of phosphorous dosage “INT1”. The test results proved that the variation of the gate threshold voltage could be effectively suppressed according to the present invention.

Evaluation for Gate Hysteresis Characteristic

When trap sites are produced in the high-k gate insulating layer (34A, 36A), agate threshold voltage exhibits a hysteresis characteristic due to the electrons trapped by the trap sites. Of course, a width of the hysteresis characteristic should become small before the performance of the MOS transistor according to the present invention can be evaluated to be superior.

First, a group A of N-channel type MOS transistor samples were produced. Each of these N-channel type MOS transistor samples featured a gate electrode structure including a high-k (HfSiON) gate electrode layer, and a gate electrode layer corresponding to the second gate electrode layer 34C. Each of these gate electrode structures was subjected to an amount of phosphorous (P) dosage.

Also, a group B of N-channel type MOS transistor samples were produced by using the production method according to the present invention. Namely, each of these N-channel type MOS transistor samples featured a gate electrode structure which was equivalent to the gate electrode structure 34. Namely, the gate electrode included a high-k (HfSiON) gate layer corresponding to the high-k gate insulating layer 34A, a first electrode layer formed on the first gate electrode layer and corresponding to the first gate electrode layer 34B, and a second electrode layer formed on the first electrode layer and corresponding to the second gate electrode layer 34C. Each of these gate electrode structures was subjected to substantially the same amount of phosphorous dosage as the gate electrode structures of the MOS transistors included in the group A.

Note, in the groups A and B, the high-k (HfSiON) gate insulating layer had a thickness which is equivalent to a silicon dioxide layer having a thickness of 1.6 nm.

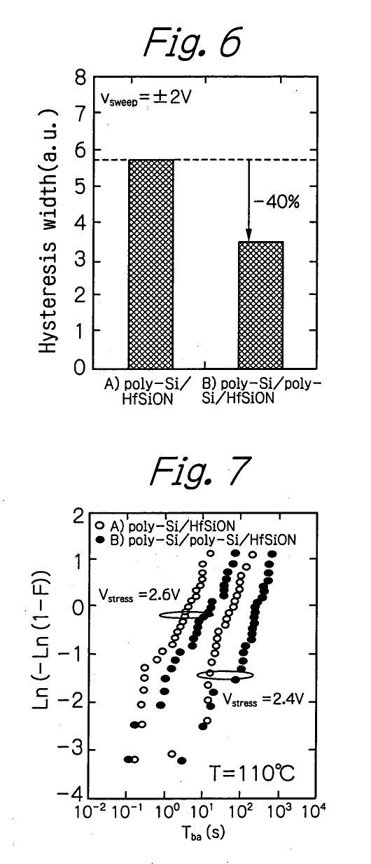

A gate voltage of =2 volts was applied to each of the MOS transistors included in the groups A and B, and was gradually raised up to +2 volts. Then, the gate voltage was gradually lowered from +2 volts to −2 volts. While the gate voltage was varied between −2 volts and +2 volts, the width of the hysteresis characteristic was measured by using a capacitance/voltage measurement method. The test results are shown in a bar graph of FIG. 6. As is apparent from the bar graph, the width of the hysteresis characteristic of the MOS transistors included in the group B become smaller by −40% in comparison with that of the MOS transistors included in the group A. Thus, the test results proved that the hysteresis characteristic could be considerably improved according to the present invention.

Evaluation for TDDB Lifetime

Although an application of more than a dielectric breakdown voltage to a gate electrode naturally causes a dielectric breakdown of a gate insulating layer, the dielectric breakdown of the gate insulating layer may occur by a continuous application of less than a dielectric breakdown voltage to the gate electrode. A period of time over which a voltage of less than the dielectric breakdown voltage is continuously applied to the gate electrode until the occurrence of the dielectric breakdown of the gate insulating layer, is defined as a time dependent dielectric breakdown (TDDB) lifetime.

When defects and trap sites are produced in the high-k gate insulating layer (34A, 36A), the TDDB lifetime may be prematurely shortened. Thus, the TDDB lifetime must be prolonged as long as possible before the performance of the MOS transistor according to the present invention can be evaluated to be superior.

First, a group A of N-channel type MOS transistor samples were produced. Each of these N-channel type MOS transistor samples featured a gate electrode structure including a high-k (HfSiON) gate electrode layer, and a gate electrode layer corresponding to the second gate electrode layer 34C. Each of these gate electrode structures was subjected to an amount of phosphorous (P) dosage.

Also, a group B of N-channel type MOS transistor samples were produced by using the production method according to the present invention. Namely, each of these N-channel type MOS transistor samples featured a gate electrode structure which was equivalent to the gate electrode structure 34. Namely, the gate electrode included a high-k (HfSiON) gate layer corresponding to the high-k gate insulating layer 34A, a first electrode layer formed on the first gate electrode layer and corresponding to the first gate electrode layer 34B, and a second electrode layer formed on the first electrode layer and corresponding to the second gate electrode layer 34C. Each of these gate electrode structures was subjected to substantially the same amount of phosphorous dosage as the gate electrode structures of the MOS transistors included in the group A.

Note, in the groups A and B, the high-k (HfSiON) gate insulating layer had a thickness which is equivalent to a silicon dioxide layer having a thickness of 1.6 nm.

A TDDB lifetime test was performed under an atmospheric temperature of 110° C. with respect to the MOS transistors included in the group A. In this TDDB lifetime test, the group A was divided into two subgroups: a first subgroup of MOS transistors, each of which was subjected to a continuous application of a gate voltage of 2.4 volts as a stress voltage; and a second subgroup of MOS transistors, each of which was subjected to an application of a gate voltage of 2.6 volts as a stress voltage.

Similarly, a TDDB lifetime test was performed under an atmospheric temperature of 110° C. with respect to the MOS transistors included in the group B. In this TDDB lifetime test, the group B was divided into two subgroups: a first subgroup of MOS transistors, each of which was subjected to a continuous application of a gate voltage of 2.4 volts as a stress voltage; and a second subgroup of MOS transistors, each of which was subjected to an application of a gate voltage of 2.6 volts as a stress voltage.

The test results are shown in a graph of FIG. 7. In this graph, the abscissa represents a time (T_{bd}) of TDDB lifetime, and the ordinate represents a distribution of TDDB lifetimes. Also, symbol “◯” represents the measured of TDDB lifetimes of the MOS transistor samples included in the group A, and symbol “●” represents the measured TDDB lifetimes of the MOS transistor samples included in the group B. As is apparent from the graph of FIG. 7, the test results proved that the TDDB lifetimes of the MOS transistors included in the group B were prolonged in comparison with that of the MOS transistors included in the group A.

Evaluation for PBIT Lifetime

When a stress voltage is continuously applied to a gate electrode, characteristics of a MOS transistor fluctuate. A period of time over which the stress voltage is continuously applied to the gate electrode until the fluctuation of the characteristics of the MOS transistor exceeds an allowable limit (e.g. 10%) of a nominal range, is defined as a positive bias temperature instability (PBTI) lifetime.

When defects and trap sites are produced in the high-k gate insulating layer (34A, 36A), the PBTI lifetime may be prematurely shortened. Thus, the PBTI lifetime must be prolonged as long as possible before the performance of the MOS transistor according to the present invention can be evaluated to be superior.

First, a group A of N-channel type MOS transistor samples were produced. Each of these N-channel type MOS transistor samples featured a gate electrode structure including a high-k (HfSiON) gate electrode layer, and a gate electrode layer corresponding to the second gate electrode layer 34C. Each of these gate electrode structures was subjected to an amount of phosphorous (P) dosage.

Also, a group B of N-channel type MOS transistor samples were produced by using the production method according to the present invention. Namely, each of these N-channel type MOS transistor samples featured a gate electrode structure which was equivalent to the gate electrode structure 34. Namely, the gate electrode included a high-k (HfSiON) gate layer corresponding to the high-k gate insulating layer 34A, a first electrode layer formed on the first gate electrode layer and corresponding to the first gate electrode layer 34B, and a second electrode layer formed on the first electrode layer and corresponding to the second gate electrode layer 34C. Each of these gate electrode structures was subjected to substantially the same amount of phosphorous dosage as the gate electrode structures of the MOS transistors included in the group A.

Note, in the groups A and B, the high-k (HfSiON) gate insulating layer had a thickness which is equivalent to a silicon dioxide layer having a thickness of 1.6 nm.

A PBTI lifetime test was performed under an atmospheric temperature of 110° C. with respect to the MOS transistors included in the group A. In this PBTI lifetime test, the group A was divided into three subgroups: a first subgroup of MOS transistors, each of which was subjected to a continuous application of a gate voltage of 1.3 volts as a stress voltage; a second subgroup of MOS transistors, each of which was subjected to an application of a gate voltage of 1.5 volts as a stress voltage; and a third subgroup of MOS transistors, each of which was subjected to an application of a gate voltage of 1.8 volts as a stress voltage.

Similarly, a PBTI lifetime test was performed under an atmospheric temperature of 110° C. with respect to the MOS transistors included in the group B. In this PBTI lifetime test, the group B was divided into three subgroups: a first subgroup of MOS transistors, each of which was subjected to a continuous application of a gate voltage of 1.3 volts as a stress voltage; a second subgroup of MOS transistors, each of which was subjected to an application of a gate voltage of 1.5 volts as a stress voltage; and a third subgroup of MOS transistors, each of which was subjected to an application of a gate voltage of 1.8 volts as a stress voltage.

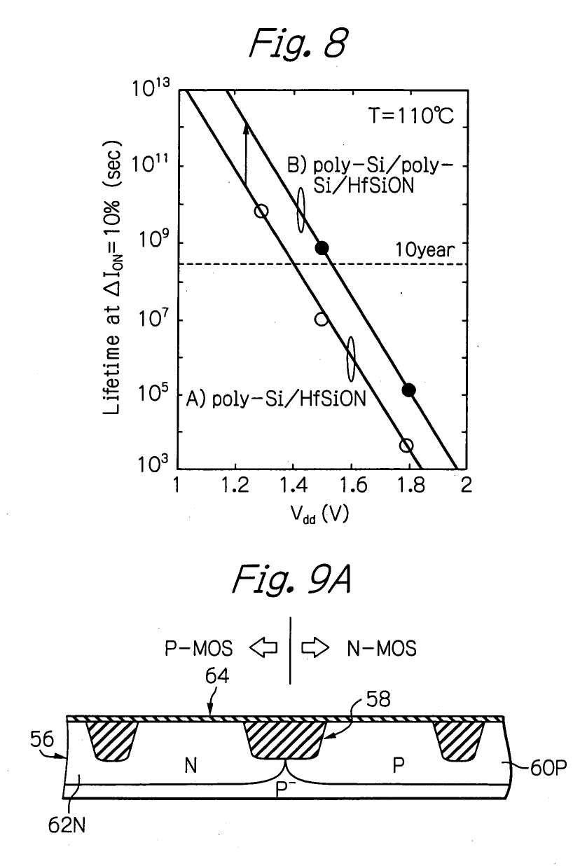

The test results are shown in a graph of FIG. 8. In this graph, the abscissa represents a stress voltage (V_{dd}) applied to a gate electrode of a MOS transistor, and the ordinate represents a PBTI lifetime of a MOS transistor. Also, symbol “◯” represents the measured PBTI lifetimes of the MOS transistor samples included in the group A, and symbol “●” represents the measured PBTI lifetimes of the MOS transistor samples included in the group B. As is apparent from the graph of FIG. 8, the test results proved that the PBTI lifetimes of the MOS transistors included in the group B were prolonged in comparison with that of the MOS transistors included in the group A.

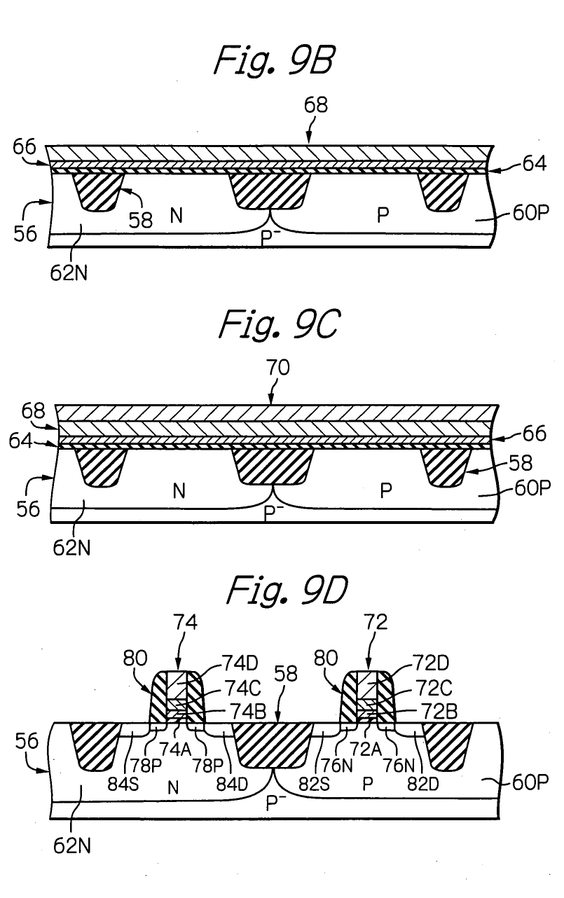

Next, with reference to FIGS. 9A to 9D, a production process for manufacturing a second embodiment of a semiconductor device featuring a complementary MOS transistor according to the present invention is explained below.

In FIG. 9A, reference 56 indicates a p⁻-type semiconductor substrate, which is derived from, for example, a p⁻-type monocrystalline silicon wafer. Similar to the aforesaid semiconductor substrate 10, a surface of the semiconductor substrate 56 is sectioned into a plurality of chip areas by forming scribe lines therein, and a part of one chip area is illustrated in a cross sectional in FIG. 9A. In this drawing, reference 58 generally indicates an element-isolation layer, which formed in the chip area concerned, by using a STI (shallow-trench isolation) method, such that a P-channel type MOS transistor-formation area “P-MOS” and an N-channel type MOS transistor-formation area “N-MOS” are defined on the surface of the chip area.

The semiconductor substrate 56 is already processed in substantially the same manner as stated with reference to FIGS. 1A to 1E. Thus, the semiconductor substrate 56 includes a P-type well region 60P and a N-type well region 62N produced therein, and a high-k insulating layer 64 formed on the surface thereof. In short, FIG. 9A corresponds to FIG. 1E.

After the formation of the high-k insulating layer 64 is completed, as shown in FIG. 9B, an amorphous silicon layer 66 is formed on the high-k insulating layer by using a suitable CVD method, at a low process temperature falling within a range from approximately 400° C. to approximately 600° C., whereby it is possible to effectively suppress reaction between the aluminum elements or rare earth elements included in the high-k insulating layer 64 and the silicon elements included in the amorphous silicon layer 66, resulting in suppression of production of trap sites in the high-k insulating layer 64. Note, during the formation of the amorphous silicon layer 66, a silane gas (SiH₄ or Si₂H₆) is introduced into a CVD chamber in which the CVD method is performed.

When the amorphous silicon layer 46 is grown to a thickness of at most 50 nm, a germane (GeH₄) gas is additionally introduced into the CVD chamber, so that a silicon/germanium (SiGe)layer 68 is formed on the amorphous silicon layer 66, as shown in FIG. 9B. Note, the thickness of the amorphous silicon layer 46 should not exceed 50 nm for the reasons stated hereinbefore.

When the silicon/germanium layer 68 is grown to a thickness of at most 100 nm, the additional introduction of the germane (GeH₄) gas into the CVD chamber is stopped, and the process temperature is raised to more than 600° C., so that a polycrystalline silicon layer 70 is formed on the silicon/germanium layer 68 until the polycrystalline silicon layer 70 is grown to a thickness of at most 100 nm, as shown in FIG. 9C. During the formation of the polycrystalline silicon layer 70, the process temperature of more than 600° C. causes crystallization in the amorphous silicone layer 66, so that the amorphous silicone layer 66 is reformed as a polycrystalline silicon layer. Note, the thickness of both the silicon/germanium layer 68 and the polycrystalline silicon layer 70 should not exceed 200 nm for the reasons stated hereinbefore.

Note, similar to the above-mentioned first embodiment, the lower polycrystalline silicon layer 66 features an average grain size which is larger than that of the upper polycrystalline silicon layer 70 which is formed at the high process temperature of more than 600° C.

After the formation of the lower polycrystalline silicon layer 66, intermediate silicon/germanium layer 68 and upper polycrystalline silicon layer 70 is completed, the semiconductor substrate 56 is further processed in substantially the same manner as stated with reference to FIGS. 1H to 1N and FIGS. 1P to 1S.

In particular, in a step corresponding to the step of FIG. 1H, N-type impurities, such as phosphorus ions (P⁺), arsenic ions (As⁺) or the like, are implanted in the layers 66, 68 and 70 at the N-channel type MOS transistor-formation area “N-MOS”. Also, in a step corresponding to the step of FIG. 1L, P-type impurities, such as boron (B⁺) or the like, are implanted in the layers 66, 68 and 70 at the P-channel type MOS transistor-formation area “P-MOS”. Thereafter, the semiconductor substrate 56 is subjected to an annealing process, in which the N-type and P-type impurities are activated and diffused in the layers 66, 68 and 70, to thereby diminish resistance of the layers 66, 68 and 70. Note, in the second embodiment, during the annealing process, an activation ratio of the impurities can be enhanced by the existence of the germanium atoms (Ge) in the intermediate silicon/germanium layer 68, and thus it is possible to effectively perform the diminishment of resistance of the layers 66, 68 and 70.

Similar to the above-mentioned first embodiment, during the annealing process, it is possible to suppress diffusion of the impurities in the high-k insulating layer 64 due to the large grain size of the lower polycrystalline silicon layer 66, resulting in suppression of production of defects in the high-k insulating layer 64.

Also, in a step corresponding to the step of FIG. 1k, gate electrode structures 72 and 74 are defined on the surfaces of the respective P-type and N-type well regions 60P and 62N.

In the second embodiment, the gate electrode structure 72 is obtained as a multi-layered structure including a high-k gate insulating layer 72A derived from the high-k insulating layer 64, a first gate electrode layer 72B derived from the lower polycrystalline silicon layer 66, a second gate electrode layer 72C derived from the intermediate silicon/germanium layer 68, and a third gate electrode layer 72D derived from the upper polycrystalline silicon layer 70, and the first, second and gate electrode layers 72B, 72C and 72D feature the N-type impurities diffused therein.

Similarly, the gate electrode structure 74 is obtained as a multi-layered structure including a high-k gate insulating layer 74A derived from the high-k insulating layer 64, a first gate electrode layer 74B derived from the lower polycrystalline silicon layer 66, a second gate electrode layer 74C derived from the intermediate silicon/germanium layer 68, and a third gate electrode layer 74D derived from the upper polycrystalline silicon layer 70, and the first, second and gate electrode layers 74B, 74C and 74D feature the P-type impurities diffused therein.

Further, in steps corresponding to the steps of FIGS. 1L to 1N, LDD regions 76N are produced in the P-type well region 60P by using the gate electrode structure 72 as a mask, and LDD regions 78P are produced in the N-type well regions 22N by using the gate electrode structure 74 as a mask.

Thereafter, in a step corresponding to the step of FIG. 1P, a side wall 80 is formed on a peripheral side face of each of the gate electrode structures 72 and 74. Then, in steps corresponding to the steps of FIGS. 1Q to 1S, source and drain regions 82S and 82D are produced in the P-type well region 60P by using the side wall 80 of the gate electrode structure 72 as a mask, and source and drain regions 84S and 84D are produced in the N-type well region 62N by using the side wall 80 of the gate electrode structure 74 as a mask.

Thereafter, an insulating interlayer (not shown) is formed on the surface of the semiconductor substrate 56 by using a suitable CVD process, and contact plugs (not shown) are formed in the insulating interlayer so as to be electrically connected to the source regions (82S, 84S) and the drain regions (82D, 84D). Then, the semiconductor substrate 56 is subjected to various processes for forming a multi-layered wiring arrangement thereon, and is then subjected to a dicing process, in which it is cut along the scribe lines, whereby the semiconductor devices are separated from each other, resulting in the manufacture of the second embodiment of the semiconductor device according to the present invention.

Finally, it will be understood by those skilled in the art that the foregoing description is of preferred embodiments of the device, and that various changes and modifications may be made to the present invention without departing from the spirit and scope thereof.

1. A semiconductor device comprising:
a semiconductor substrate (10; 56); and
at least one electrode structure (34, 36; 72, 74) provided on a surface of said semiconductor substrate,
wherein said electrode structure is constructed as a multi-layered electrode structure including:
an insulating layer (34A, 36A; 72A, 74A) formed on the surface of said semiconductor substrate and composed of a dielectric material exhibiting a dielectric constant larger than that of silicon dioxide;
a lower electrode layer (34B, 36B; 72B, 74B) formed on said insulating layer and composed of polycrystalline material; and
an upper electrode layer (34C, 36C; 72D, 74D) formed on said lower electrode layer and composed of polycrystalline material, said lower electrode layer featuring an average grain size of polycrystalline material which is larger than that of polycrystalline material of said upper electrode layer.

2. The semiconductor device as set forth in claim 1, wherein said polycrystalline material is polycrystalline silicon.

3. The semiconductor device as set forth in claim 1, wherein said lower electrode layer (34B, 36B; 72B, 74B) has a thickness of less than approximately 50 nm.

4. The semiconductor device as set forth in claim 1, wherein said upper electrode layer (34B, 36B; 72D, 74D) has a thickness of less than approximately 200 nm.

5. The semiconductor device as set forth in claim 1, wherein said insulating layer (34A, 36A; 72A, 74A) is composed of aluminum oxide, aluminum nitride, aluminum oxy-nitride, and aluminum silicate.

6. The semiconductor device as set forth in claim 1, wherein said insulating layer (34A, 36A; 72A, 74A) is composed of one selected from a group consisting of oxides, nitrides, oxy-nitrides, aluminates, and silicates, which are obtained from zirconium (Zr), hafnium (Hf), tantalum (Ta), yttrium (Y), and lanthanoid (La, Ce, Pr, Nd, Pm, Sm, Eu, Gd, Tb, Dy, Ho, Er, Tm, Yb, Lu).

7. The semiconductor device as set forth in claim 2, wherein said lower electrode layer (34B, 36B; 72B, 74B) is formed as an amorphous silicon layer by using a chemical vapor deposition method at a process temperature falling a range from 400° C. to 600° C., and crystallization is caused in said amorphous silicone layer under a process temperature of more than 600° C., resulting in formation of said lower electrode layer.

8. The semiconductor device as set forth in claim 2, wherein said multi-layered electrode structure (72, 74) further includes an intermediate electrode layer (72C, 74C) intervened between said lower electrode layer (72B, 74B) and said upper electrode layer (72D, 74D), and said intermediate electrode layer is formed as a silicon/germanium layer.

9. The semiconductor device as set forth in claim 8, wherein said lower electrode layer (72B, 74B) has a thickness of less than approximately 50 nm, and both said intermediate electrode layer (72C, 74C) and said upper electrode layer (72D, 74D) have a thickness of less than approximately 200 nm.

10. The semiconductor device as set forth in claim 1, featuring at least one metal oxide semiconductor transistor, wherein said multi-layered structure is defined as a multi-layered gate electrode structure for said metal oxide semiconductor transistor, said insulating layer (34A, 36A; 72A, 74A) serving as a gate insulating layer, said lower electrode layer (34B, 36B; 72B, 74B) serving as a lower gate electrode layer, said upper electrode layer (34C, 36C; 72D, 74D) serving as an upper gate electrode layer.

11. The semiconductor device as set forth in claim 10, wherein said polycrystalline material is polycrystalline silicon.

12. The semiconductor device as set forth in claim 10, wherein said lower gate electrode layer (34B, 36B; 72B, 74B) has a thickness of less than approximately 50 nm.

13. The semiconductor device as set forth in claim 10, wherein said upper gate electrode layer (34B, 36B; 72D, 74D) has a thickness of less than approximately 200 nm.

14. The semiconductor device as set forth in claim 10, wherein said gate insulating layer (34A, 36A; 72A, 74A) is composed of aluminum oxide, aluminum nitride, aluminum oxy-nitride, and aluminum silicate.

15. The semiconductor device as set forth in claim 10, wherein said gate insulating layer (34A, 36A; 72A, 74A), is composed of one selected from a group consisting of oxides, nitrides, oxy-nitrides, aluminates, and silicates, which are obtained from zirconium (Zr), hafnium (Hf), tantalum (Ta), yttrium (Y), and lanthanoid (La, Ce, Pr, Nd, Pm, Sm, Eu, Gd, Tb, Dy, Ho, Er, Tm, Yb, Lu).

16. The semiconductor device as set forth in claim 11, wherein said lower gate electrode layer (34B, 36B; 72B, 74B) is formed as an amorphous silicon layer by using a chemical vapor deposition method at a process temperature falling a range from 400° C. to 600° C., and crystallization is caused in said amorphous silicone layer under a process temperature of more than 600° C., resulting in formation of said lower gate electrode layer.

17. The semiconductor device as set forth in claim 11, wherein said multi-layered gate electrode structure (72, 74) further includes an intermediate gate electrode layer (72C, 74C) intervened between said lower gate electrode layer (72B, 74B) and said upper gate electrode layer (72D, 74D), and said intermediate gate electrode layer is formed as a silicon/germanium layer. 18. The semiconductor device as set forth in claim 17, wherein said lower gate electrode layer (72B, 74B) has a thickness of less than approximately 50 nm, and both said intermediate gate electrode layer (72C, 74C) and said upper gate electrode layer (72D, 74D) have a thickness of less than approximately 200 nm.
